(19) United States
(12) Patent Application Publication
(10) Pub. No.: US 2023/0203661 A1
(43) Pub. Date: Jun. 29, 2023

(54) APPARATUS AND METHOD FOR PERFORMING PLASMA ENHANCED ATOMIC LAYER DEPOSITION EMPLOYING VERY HIGH FREQUENCY

(71) Applicant: AJOU UNIVERSITY INDUSTRY-ACADEMIC COOPERATION FOUNDATION, Gyeonggi-do (KR)

(72) Inventors: Il Kwon OH, Gyeonggi-do (KR); Min-Jeong RHEE, Gyeonggi-do (KR)

(73) Assignee: AJOU UNIVERSITY INDUSTRY-ACADEMIC COOPERATION FOUNDATION, GYEONGGI-DO (KR)

(21) Appl. No.: 18/090,242

(22) Filed: Dec. 28, 2022

(30) Foreign Application Priority Data
Dec. 28, 2021 (KR) 10-2021-0189551

(51) Int. Cl. C23C 16/505; H01J 37/32; C23C 16/455; C23C 16/46; C23C 16/34

(52) U.S. Cl. CPC C23C 16/505; H01J 37/321; H01J 37/32449; H01J 37/32568; H01J 37/32183; H01J 37/32724; C23C 16/45536; C23C 16/45544; C23C 16/46; C23C 16/345; H01J 2237/332; H01J 2237/2001

(57) ABSTRACT

The present invention relates to an apparatus and method for forming a silicon nitride film by performing plasma enhanced atomic layer deposition (PE-ALD) employing very high frequency (VHF). An atomic layer deposition apparatus according to an embodiment of the present invention may comprise: a chamber providing a space in which a process is performed; a substrate support unit for supporting a substrate in the chamber; a gas supply unit for supplying gas to the chamber; an exhaust unit for discharging gas in the chamber; a plasma generation unit installed in the chamber to generate plasma in the chamber; and a VHF (very high frequency) power source for applying a VHF band signal to the plasma generation unit.

### CROSS-REFERENCE TO RELATED APPLICATION

This application claims priority to and the benefit of Korean Patent Application No. 10-2021-0189551, filed on Dec. 28, 2021, the disclosure of which is incorporated herein by reference in its entirety.

### GOVERNMENT SUPPORT

This application was supported by Ministry of Trade, Industry and Energy of Republic of Korea (No. 00143986 and 1415181732).

### TECHNICAL FIELD

The present invention relates to an apparatus and method for forming a silicon nitride film by performing plasma enhanced atomic layer deposition (PE-ALD) employing very high frequency (VHF).

### BACKGROUND ART

As a technology for depositing a thin film on a substrate, an atomic layer deposition (ALD) process for depositing a thin film in an atomic layer unit is being studied. The atomic layer deposition process has excellent step coverage compared to the existing chemical vapor deposition (CVD) process and can deposit a thin film with a uniform thickness over a large area, and thus, has gained a great response in the manufacture of semiconductor devices having a three-dimensional structure in nanometer.

The atomic layer deposition process is classified into thermal atomic layer deposition (thermal ALD) and plasma enhanced atomic layer deposition (plasma enhanced ALD or PE-ALD) depending on the reactants used in the process. In the thermal ALD, a reactant reacting with a precursor material is provided in a gaseous state, whereas in the plasma-enhanced ALD, a reactant is provided in a plasma state. A conventional PE-ALD process has generally used a signal having an RF band, i.e., a frequency of 13.56 MHz, to generate plasma. However, the PE-ALD process using a signal in the RF band has a problem in that it has limitations in deposition rate and thin film density, and thus cannot meet the demand for manufacturing semiconductor circuits whose degree of integration continues to increase.

On the other hand, among various deposition films, a silicon nitride film is deposited at a low temperatures and has excellent properties, and thus is expected to be applicable as an insulating thin film for next-generation semiconductor devices. In particular, the silicon nitride film is used as an anti-oxidation mask in a local oxidation of silicon (LOCOS) process and also as a final protective film to protect a device from contaminants that deteriorate semiconductor characteristics, such as moisture or Na+, and thus, its importance is gradually being emphasized.

Therefore, research on a method for effectively depositing the silicon nitride film while using the PE-ALD process is required.

### DISCLOSURE

### Technical Problem

It is an object of the present invention to provide an atomic layer deposition apparatus and method capable of depositing a silicon nitride film using nitrogen plasma treatment while performing a PE-ALD process with improved deposition rate and thin film density compared to conventional ones.

### Technical Solution

An atomic layer deposition apparatus according to an embodiment of the present invention may comprise: a chamber providing a space in which a process is performed; a substrate support unit for supporting a substrate in the chamber; a gas supply unit for supplying gas to the chamber; an exhaust unit for discharging gas in the chamber; a plasma generation unit installed in the chamber to generate plasma in the chamber; and a VHF (very high frequency) power source for applying a VHF band signal to the plasma generation unit.

The gas supply unit may supply a silicon precursor gas, a plasma source gas, or a purge gas to the chamber.

After the substrate is placed in the chamber, the gas supply unit may repeat a cycle in which the silicon precursor gas is supplied at a predetermined first flow rate for a predetermined first time period, the purge gas is supplied at a predetermined second flow rate for a predetermined second time period, the plasma source gas is supplied at a predetermined third flow rate for a predetermined third time period, and the purge gas is supplied at the second flow rate for the second time period.

The plasma generation unit may include at least one of: an upper electrode and a lower electrode installed to face each other with the substrate interposed therebetween to form an electric field in the chamber; and a coil installed on the top or side of the chamber to form an electromagnetic field in the chamber.

The VHF power source may apply a signal having a frequency of 30 to 300 MHz to the plasma generation unit.

The atomic layer deposition apparatus may further include an impedance matching unit connected between the VHF power source and the plasma generation unit to match an output impedance of the VHF power source and an input impedance of the plasma generation unit.

The atomic layer deposition apparatus may further include a heating unit installed in the substrate support unit to heat the substrate.

The gas supply unit may supply a silicon precursor selected from the group consisting of a chloride-based silicon precursor, an amide-based silicon precursor and combinations thereof as the silicon precursor gas at 1 sccm for 3 seconds or longer.

The gas supply unit may supply a nitrogen-containing reactant as the plasma source gas at 200 sccm for 2 seconds or longer.

The gas supply unit may supply argon as the purge gas at 50 sccm for 6 seconds or longer.

The VHF power source may apply a signal having a frequency of 60 MHz to the plasma generation unit.

The heating unit may heat the substrate to 150 to 200° C.

An atomic layer deposition method according to an embodiment of the present invention may include the steps of: supplying a silicon precursor gas to a chamber in which a substrate is disposed; purging the chamber by supplying a purge gas to the chamber; applying a VHF band signal to a plasma generation unit installed in the chamber while supplying a plasma source gas to the chamber; and purging the chamber by supplying the purge gas to the chamber.

The step of applying a VHF band signal may include applying a signal having a frequency of 30 to 300 MHz to the plasma generation unit.

The step of supplying a silicon precursor gas may include supplying a silicon precursor selected from the group consisting of a chloride-based silicon precursor, an amide-based silicon precursor and combinations thereof to the chamber at 1 sccm for 3 seconds or longer.

The step of applying a VHF band signal while supplying a plasma source gas may include supplying a nitrogen-containing reactant to the chamber at 200 sccm for 2 seconds or longer.

The step of applying a VHF band signal while supplying a plasma source gas may include applying a signal having a frequency of 60 MHz to the plasma generation unit.

The step of purging the chamber may include supplying argon to the chamber at 50 sccm for 6 seconds or longer.

The atomic layer deposition method may further include a step of heating the substrate to a predetermined temperature before the step of supplying a silicon precursor gas.

The step of heating the substrate to a predetermined temperature may include heating the substrate to 180° C.

### Advantageous Effects

According to an embodiment of the present invention, a silicon nitride film can be deposited using nitrogen plasma treatment, and a deposition rate and a thin film density by a PE-ALD process can be improved compared to the prior art.

According to an embodiment of the present invention, the productivity of the semiconductor process can be improved due to the improved deposition rate and thin film density by the PE-ALD process.

### DESCRIPTION OF DRAWINGS

FIG. 1 is a schematic diagram of an atomic layer deposition apparatus according to an embodiment of the present invention.

FIG. 2 is a diagram for explaining a process of providing a process gas and a VHF signal according to an embodiment of the present invention.

FIG. 3 is an exemplary flowchart of an atomic layer deposition method according to an embodiment of the present invention.

### BEST MODES OF THE INVENTION

Hereinafter, embodiments of the present invention will be described in detail with reference to the accompanying drawings.

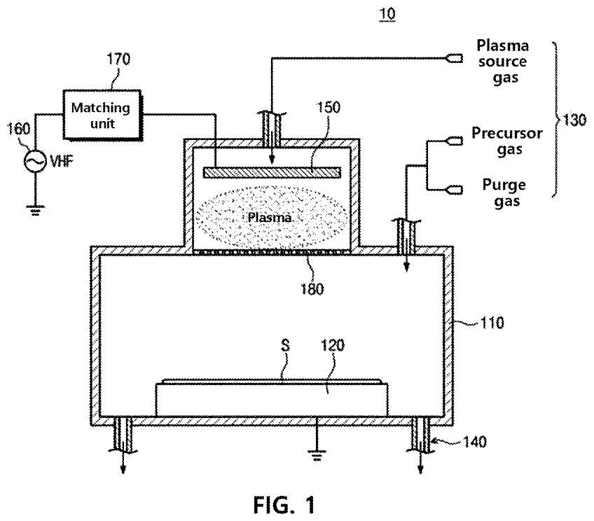

FIG. 1 is a schematic diagram of an atomic layer deposition apparatus 10 according to an embodiment of the present invention.

As shown in FIG. 1, the atomic layer deposition apparatus 10 may include a chamber 110, a substrate support unit 120, a gas supply unit 130, an exhaust unit 140, a plasma generation unit 150, and a VHF power source (160).

The chamber 110 provides a space in which a process is performed. The substrate support unit 120 supports the substrate S in the chamber 110. The gas supply unit 130 supplies gas to the chamber 110. The exhaust unit 140 discharges gas in the chamber 110. The plasma generation unit 150 is installed in the chamber 110 to generate plasma in the chamber 110. The VHF power source 160 applies a VHF (very high frequency) band signal to the plasma generation unit 150.

According to an embodiment of the present invention, the gas supply unit 130 may supply a silicon precursor gas, a plasma source gas, or a purge gas to the chamber 110. In other words, during the process, the gas supply unit 130 may alternately supply several types of gases (in particular, silicon precursor gas and plasma source gas) one by one, instead of supplying them all at once.

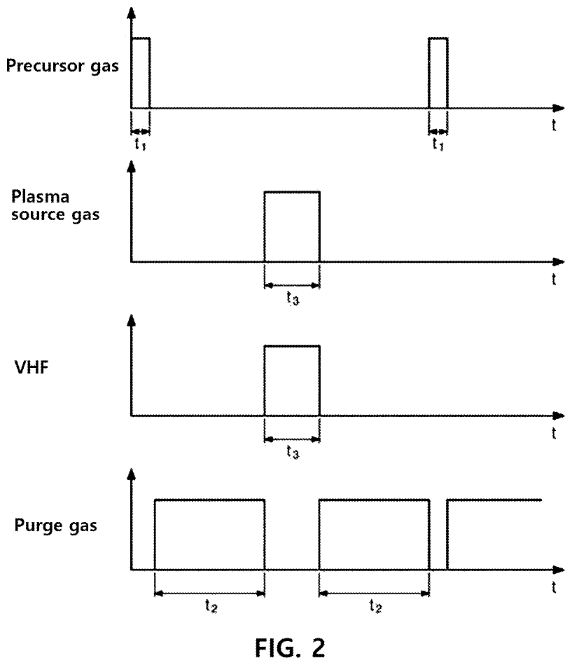

FIG. 2 is a diagram for explaining a process of providing a process gas and a VHF signal according to an embodiment of the present invention.

Referring to FIG. 2, after the substrate S is placed in the chamber 110, the gas supply unit 130 may supply the silicon precursor gas to the chamber 110 at a predetermined first flow rate for a predetermined first time period t1. Then, the gas supply unit 130 may supply the purge gas to the chamber 110 at a predetermined second flow rate for a predetermined second time period t2.

Thereafter, the gas supply unit 130 may supply the plasma source gas to the chamber 110 at a predetermined third flow rate for a predetermined third time period t3. Then, the gas supply unit 130 may supply the purge gas at the second flow rate for the second time period t2.

As such, the gas supply unit 130 may supply process gases to the chamber 110 in the order of the silicon precursor gas, the purge gas, the plasma source gas, and the purge gas to deposit a thin film in an atomic layer unit on the substrate S.

Furthermore, the gas supply unit 130 may supply the silicon precursor gas, the purge gas, the plasma source gas, and the purge gas in one cycle, and repeat the cycle a predetermined number of times so that the thin film can be deposited on the substrate S to a desired thickness.

Referring back to FIG. 1, the plasma generation unit 150 receives a VHF band signal from the VHF power source 160 and converts the plasma source gas supplied to the chamber 110 into a plasma state.

According to an embodiment, the plasma generation unit 150 may include an upper electrode and a lower electrode installed to face each other with the substrate S interposed therebetween to form an electric field in the chamber 110. That is, the plasma generation unit 150 may be a capacitively coupled plasma (CCP)-type plasma source. The plasma generation unit 150 shown in FIG. 1 includes an upper electrode 150 installed in the upper part of the chamber 110 and a lower electrode (not shown) disposed on the substrate support unit 120.

According to another embodiment, the plasma generation unit may include a coil installed on the top or side of the chamber 110 to form an electromagnetic field in the chamber 110. In other words, the plasma generation unit 150 may be an inductively coupled plasma (ICP)-type plasma source.

According to an embodiment, the plasma generation unit may include both the coil, the ICP-type plasma source, and parallel plate electrodes, the CCP-type plasma source.

The VHF power source 160 supplies a VHF band signal to the plasma generation unit 150 to supply power required for the plasma generation.

According to one embodiment of the present invention, the VHF power source 160 may apply a signal having a frequency of 30 to 300 MHz to the plasma generation unit 150, but the frequency may be used in various values without being limited to 30 to 300 MHz as long as it is higher than the conventionally used RF band (e.g., 13.56 MHz).

Referring to FIG. 2, the VHF power source 160 may supply a VHF band signal to the plasma generation unit 150 while the plasma source gas is supplied to the chamber 110. Accordingly, the VHF band signal may be applied to the plasma generation unit 150 for the third time period.

Referring back to FIG. 1, the atomic layer deposition apparatus 10 may further include an impedance matching unit 170 connected between the VHF power source 160 and the plasma generation unit 150 to match an output impedance of the VHF power source 160 and an input impedance of the plasma generation unit 150.

According to an embodiment, the atomic layer deposition apparatus 10 may further include a shower head 180 installed above the substrate S to uniformly supply the plasma generated by the plasma generation unit 150 onto the substrate S.

In addition, although not shown in FIG. 1, the atomic layer deposition apparatus 10 may further include a heating unit installed in the substrate support unit 120 to heat the substrate S. The heating unit may maintain or control the substrate S at a predetermined temperature during the process to achieve a process temperature for forming a thin film on the substrate S.

The exhaust unit 140 may discharge gas or reaction by-products remaining in the chamber 110 to the outside by using a pump or the like. In addition, the exhaust unit 140 may adjust a pressure in the chamber to a predetermined pressure during the process.

According to one embodiment of the present invention, the gas supply unit 130 may supply a silicon precursor selected from the group consisting of a chloride-based silicon precursor, an amide-based silicon precursor and combinations thereof as the silicon precursor gas to the chamber 110.

For example, the silicon precursor may include at least one selected from the group consisting of SiH₂Cl₂, SiHCl₃, SiH₃Cl, SiCl₄, Si₂Cl₆, Si₃Cl₈, Si₄Cl₁₀, RₓSiCl₄₋ₓ (x is an integer of 0<x<6), RₓSi₂Cl₆₋ₓ (x is an integer of 0<x<6), RₓSi₃Cl₈₋ₓ (x is an integer of 0<x<8), RₓSi₄Cl₁₀₋ₓ (x is an integer of 0<x<10), H₂Si[N(C₂H₅)₂]₂(BTBAS), SiH₂[N(C₂H₅)₂]₂(BDEAS), SiH[N(CH₃)₂]₃(TDMAS), SiH₃[N(C₃H₇)₂](DIPAS), SiH₃[N(CH₃)₂](DMAS), SiH₃[N(CH₃C₂H₅)](EMAS), SiH₃[N(C₂H₅)₂](DEAS), (R¹R²N) nSiH₄₋ₙ (n is an integer of 0<n<4), (R¹R²R³Si)ₙNH₃₋ₙ (n is an integer of 0<n<3), (R¹R²R³Si)ₙNₓH_{y} (n, x and y are integers of n>0, x>0, and y>0, respectively), ((CH₃)₃Si)₂N(SiH(CH₃)N(CH₃)₂)[dimethyl amino methyl silyl)bis(trimethyl silyl)amine], (CH₃)₃SiN(SiH(CH₃)N(CH₃)₂)₂[Bis(dimethyl amino methyl silyl)(trimethyl silyl)amine], C₄H₁₇NSi₃[Bis(dimethylsilyl)silylamine], ((CH₃)₂N)SiH(CH₃))₃N[Tris(dimethyl amino)(methyl silyl)amine], C₇H₂₅N₃Si₃[Bis(dimethyl amino methyl silyl)(methyl silyl)amine], C₈H₂₂N₂Si₂[1,3-di-isopropyl amino-2,4-dimethyl cyclosilazane] having a ring structure, C₆H₁₈N₂Si₂[1,2,2,3,4,4-hexamethyl-1,3,2,4-diazadisiletidine], alkoxide, Si(C₂H₅O)₄, Si(NCO)₄, SiH₄, and Si(II) precursor, such as 1,4-di-isopropyl-1,3-diazabutadiene silicon, 1,4-di-methyl-1,3-diazabutadiene silicon, 1,4-di-ethyl-1,3-diazabutadiene silicon, 1,4-di-isopropyl-1,3-didiazabutadiene silicon, 1,4-di-butyl-1,3-diazabutadiene silicon, 1,4-di-aza-butane-1,4-di-tert-butyl-2,2-di-methyl silicon, 4-tert-butyl-1,4-di-aza-butane-3,3-di-methyl-1-ethyl silicon, (R¹NCH═CHNR²)Si(II), (R¹NR²NR³)Si(II), and combinations thereof, but is not limited thereto. Here, each of the R's included in the silicon precursors may be independently selected from the group consisting of hydrogen, a C₁₋₂₀ linear or branched alkyl group, and a C₃₋₂₀ unsaturated or aromatic ring group. For example, each of the R's may be independently selected from the group consisting of C₁₋₂₀, C₁₋₁₅, C₁₋₁₀, C₁₋₆, C₁₋₅, and C₁₋₃ linear or branched alkyl groups. For example, each of the R's may be selected from the group consisting of methyl, ethyl, propyl, butyl, pentyl, hexyl, heptyl, octyl, nonyl, decyl, undecyl, dodecyl, tridecyl, tetradecyl, pentadecyl, hexadecyl, heptadecyl, octadecyl, nonadecyl, eicosyl, and all possible isomers thereof, but is not limited thereto.

In addition, the gas supply unit 130 may supply a nitrogen-containing reactant such as nitrogen (N₂) or ammonia (NH₃) gas as the plasma source gas to the chamber 110.

For example, the nitrogen-containing reactant may be at least one selected from the group consisting of N₂, NH₃, RₓNH₃₋ₓ, N₂H₄, RₓN₂H₄₋ₓ, and combinations thereof, but is not limited thereto. Here, each of the R's included in the nitrogen-containing reactants is independently a C₁₋₂₀ linear or branched alkyl group. For example, each of the R's may be independently selected from the group consisting of C₁₋₂₀, C₁₋₁₅, C₁₋₁₀, C₁₋₆, C₁₋₅, and C₁₋₃ linear or branched alkyl groups. For example, each of the R's may be independently selected from the group consisting of methyl, ethyl, propyl, butyl, pentyl, hexyl, heptyl, octyl, nonyl, decyl, undecyl, dodecyl, tridecyl, tetradecyl, pentadecyl, hexadecyl, heptadecyl, octadecyl, nonadecyl, eicosyl, and all possible isomers thereof, but is not limited thereto.

Then, the gas supply unit 130 may supply argon (Ar) as the purge gas to the chamber 110.

By supplying a series of gases as described above, the atomic layer deposition apparatus 10 may deposit a silicon nitride film in an atomic layer unit on the substrate S.

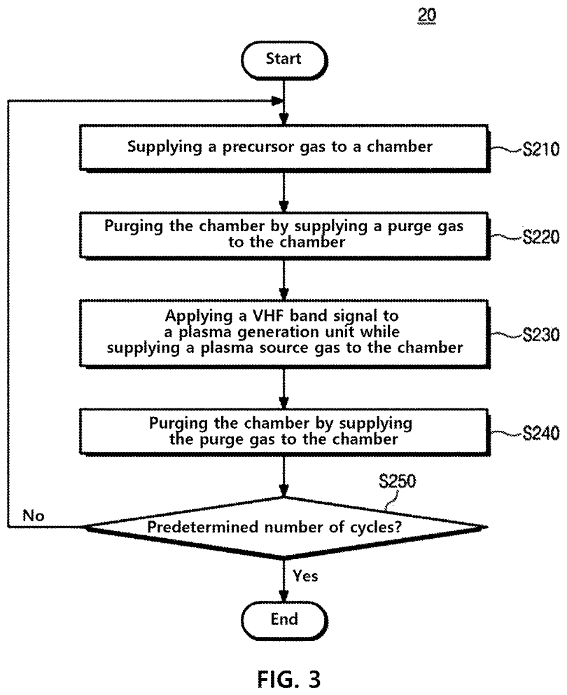

FIG. 3 is an exemplary flowchart of an atomic layer deposition method 20 according to an embodiment of the present invention.

The atomic layer deposition method 20 of depositing a metal oxide thin film in an atomic layer unit on the substrate S may be performed using the atomic layer deposition apparatus 10 according to the embodiment of the present invention described above.

As shown in FIG. 3, the atomic layer deposition method 20 may include the steps of: supplying a silicon precursor gas to a chamber 110 in which a substrate S is disposed (step S210); purging the chamber 110 by supplying a purge gas to the chamber 110 (step S220); applying a VHF band signal to a plasma generation unit 150 installed in the chamber 110 while supplying a plasma source gas to the chamber 110 (step S230); and purging the chamber 110 by supplying the purge gas to the chamber 110 (step S240).

In addition, in the atomic layer deposition method 20, the aforementioned steps S210 to S240 as one cycle may be repeated a determined number of times to deposit a thin film having a desired thickness on the substrate S.

According to an embodiment, the step of supplying a silicon precursor gas (S210) may include supplying a silicon precursor selected from the group consisting of a chloride-based silicon precursor, an amide-based silicon precursor and combinations thereof to the chamber 110 at 1 sccm for 3 seconds or longer.

According to an embodiment, the step of applying a VHF band signal while supplying a plasma source gas (S230) may include supplying a nitrogen-containing reactant such as nitrogen (N₂) or ammonia (NH₃) gas to the chamber 110 at 200 sccm for 2 seconds or longer.

In addition, the step of applying a VHF band signal (S230) may include applying a signal having a frequency of 30 to 300 MHz to the plasma generation unit 150.

Specifically, the step of applying a VHF band signal (S230) may include applying a signal having a frequency of 60 MHz to the plasma generation unit 150.

According to an embodiment, the step of purging the chamber 110 (S240) may include supplying argon (Ar) to the chamber 110 at 50 sccm for 6 seconds or longer.

According to an embodiment of the present invention, the atomic layer deposition method 20 may further include a step of heating the substrate S to a predetermined temperature before the step of supplying a silicon precursor gas (S210).

The step of heating the substrate S to a predetermined temperature may include heating the substrate S to a temperature of 150 to 200° C., specifically 180° C.

In the above, there has been described embodiments of the present invention for the atomic layer deposition of a metal oxide thin film on a substrate by a PE-ALD process using a VHF band signal. According to the embodiments of the present invention, a silicon nitride film can be deposited using nitrogen plasma treatment, and a deposition rate and a thin film density can be improved compared to the prior art using a RF band signal, thereby improving the productivity of the semiconductor process.

Although embodiments of the present invention have been described so far, the embodiments are only for explaining the idea of the present invention, and the present invention is not limited thereto. Those skilled in the art will understand that various modifications can be made to the above-described embodiments. The scope of the present invention is defined only by the interpretation of the appended claims.

### DESCRIPTION OF REFERENCE NUMERALS AND SYMBOLS

10: atomic layer deposition apparatus
110: chamber
120: substrate support unit
130: gas supply unit
140: exhaust unit
150: plasma generation unit
160: VHF power source
170: impedance matching unit
180: shower head

1. An atomic layer deposition apparatus comprising:
a chamber providing a space in which a process is performed;
a substrate support unit for supporting a substrate in the chamber;
a gas supply unit for supplying gas to the chamber;
an exhaust unit for discharging gas in the chamber;
a plasma generation unit installed in the chamber to generate plasma in the chamber; and
a VHF (very high frequency) power source for applying a VHF band signal to the plasma generation unit.

2. The atomic layer deposition apparatus according to claim 1, wherein the gas supply unit supplies a silicon precursor gas, a plasma source gas, or a purge gas to the chamber.

3. The atomic layer deposition apparatus according to claim 2, wherein after the substrate is placed in the chamber, the gas supply unit repeats a cycle in which the silicon precursor gas is supplied at a predetermined first flow rate for a predetermined first time period, the purge gas is supplied at a predetermined second flow rate for a predetermined second time period, the plasma source gas is supplied at a predetermined third flow rate for a predetermined third time period, and the purge gas is supplied at the second flow rate for the second time period.

4. The atomic layer deposition apparatus according to claim 1, wherein the plasma generation unit includes at least one of:
an upper electrode and a lower electrode installed to face each other with the substrate interposed therebetween to form an electric field in the chamber; and
a coil installed on the top or side of the chamber to form an electromagnetic field in the chamber.

5. The atomic layer deposition apparatus according to claim 1, wherein the VHF power source applies a signal having a frequency of 30 to 300 MHz to the plasma generation unit.

6. The atomic layer deposition apparatus according to claim 1, further including an impedance matching unit connected between the VHF power source and the plasma generation unit to match an output impedance of the VHF power source and an input impedance of the plasma generation unit.

7. The atomic layer deposition apparatus according to claim 1, further including a heating unit installed in the substrate support unit to heat the substrate.

8. The atomic layer deposition apparatus according to claim 3, wherein the gas supply unit supplies a silicon precursor selected from the group consisting of a chloride-based silicon precursor, an amide-based silicon precursor and combinations thereof as the silicon precursor gas at 1 sccm for 3 seconds or longer.

9. The atomic layer deposition apparatus according to claim 3, wherein the gas supply unit supplies a nitrogen-containing reactant as the plasma source gas at 200 sccm for 2 seconds or longer.

10. The atomic layer deposition apparatus according to claim 3, wherein the gas supply unit supplies argon as the purge gas at 50 sccm for 6 seconds or longer.

11. The atomic layer deposition apparatus according to claim 5, wherein the VHF power source applies a signal having a frequency of 60 MHz to the plasma generation unit.

12. The atomic layer deposition apparatus according to claim 7, wherein the heating unit heats the substrate to 150 to 200° C.

13. An atomic layer deposition method including the steps of:
supplying a silicon precursor gas to a chamber in which a substrate is disposed;
purging the chamber by supplying a purge gas to the chamber;
applying a VHF band signal to a plasma generation unit installed in the chamber while supplying a plasma source gas to the chamber; and
purging the chamber by supplying the purge gas to the chamber.

14. The atomic layer deposition method according to claim 13, wherein the step of applying a VHF band signal includes applying a signal having a frequency of 30 to 300 MHz to the plasma generation unit.

15. The atomic layer deposition method according to claim 13, wherein the step of supplying a silicon precursor gas includes supplying a silicon precursor selected from the group consisting of a chloride-based silicon precursor, an amide-based silicon precursor and combinations thereof to the chamber at 1 sccm for 3 seconds or longer.

16. The atomic layer deposition method according to claim 13, wherein the step of applying a VHF band signal while supplying a plasma source gas includes supplying a nitrogen-containing reactant to the chamber at 200 sccm for 2 seconds or longer.

17. The atomic layer deposition method according to claim 16, wherein the step of applying a VHF band signal while supplying a plasma source gas includes applying a signal having a frequency of 60 MHz to the plasma generation unit.

18. The atomic layer deposition method according to claim 13, wherein the step of purging the chamber includes supplying argon to the chamber at 50 sccm for 6 seconds or longer.

19. The atomic layer deposition method according to claim 13, further including a step of heating the substrate to a predetermined temperature before the step of supplying a silicon precursor gas.

20. The atomic layer deposition method according to claim 19, wherein the step of heating the substrate to a predetermined temperature includes heating the substrate to 180° C.
